(19) United States
(12) Patent Application Publication
(10) Pub. No.: US 2018/0238940 A1
(43) Pub. Date: Aug. 23, 2018

(54) CURRENT DETECTION CIRCUIT

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventor: Yuuki Sugisawa, Yokkaichi, Mie (JP)

(21) Appl. No.: 15/752,964

(22) PCT Filed: Aug. 16, 2016
(86) PCT No.: PCT/JP2016/073908

§ 371 Date: Feb. 15, 2018

(30) Foreign Application Priority Data
Aug. 20, 2015 (JP) 2015-162964

(51) Int. Cl. G01R 19/25; G01R 19/255; G01R 19/257; G01R 1/20; H03K 4/50

(52) U.S. Cl. CPC G01R 19/2509; G01R 19/255; H03K 4/50; G01R 1/203; G01R 19/257

(57) ABSTRACT

Provided is a current detection circuit that can detect current in a wide dynamic range, with high precision, and with good step response. Voltage that is generated between both ends of a resistor connected between a high-voltage power supply and a load is amplified by amplifiers and compared, by comparators, to the voltage of a saw-tooth wave signal; the lengths of signals indicating the comparison results from the comparators during an inclined period in which the voltage of the saw-tooth wave signal linearly and gradually increases or decreases and the length of the inclined period are detected; and the current flowing to the resistor is detected on the basis of the ratio between the detected lengths.

### CROSS-REFERENCE TO RELATED ART

This application is the U.S. national stage of PCT/JP2016/073908 filed Aug. 16, 2016 which claims priority of Japanese Patent Application No. JP 2015-162964 filed on Aug. 20, 2015.

### TECHNICAL FIELD

The present invention relates to a current detection circuit that detects current flowing between a power supply and a load via a resistor.

### BACKGROUND

Many methods for detecting current flowing to a load such as a battery or a motor have been proposed thus far. A Hall device or a shunt resistor is typically used in a current sensor for detecting DC current. An analog detection result from the current sensor is converted into a digital value as necessary.

For example, JP 2013-92140A discloses a control device that uses a current sensor including a Hall device to detect the value of current that charges/is discharged by a vehicle battery. The current sensor has an iron core, and thus the detection results contain offset error caused by the effects of residual magnetism and hysteresis. As such, according to JP 2013-92140A, the detection results from the current sensor are corrected by an offset correction device.

When a detection result from a current sensor is subjected to A/D conversion to obtain a digital value, there are situations, such as with an A/D converter built into a microcomputer, where the number of bits is insufficient. Nevertheless, it is desirable to detect current with high precision and convert the result into a digital value without using an expensive external AM converter.

In response to this, Japanese Patent No. 4899843 discloses a motor control device that detects current flowing in a PM motor (a permanent magnet electric motor) using a current sensor and converts the detection result into a 1-bit signal (bitstream) using a ΔΣ (delta-sigma) modulator.

However, the current sensor according to JP 2013-92140A, which includes a Hall device, has problems in that it is difficult to detect current with high precision across a wide dynamic range, the structure of the sensor is complicated, and the sensor is relatively expensive. Additionally, compared to a successive comparison-type A/D converter, the ΔΣ modulator disclosed in Japanese Patent No. 4899843 has problems in that the ΔΣ modulator oversamples and thus consumes a high amount of power, and furthermore has poor step response, which leads to longer settling times in the conversion.

Having been achieved in light of the foregoing circumstances, an object of the present invention is to provide a current detection circuit that can detect current in a wide dynamic range, with high precision, and with good step response.

### SUMMARY

A current detection circuit according to an aspect of the present invention is a current detection circuit that detects current flowing between a power supply and a load via a resistor, the circuit including: a generating unit that generates a triangle wave signal or a saw-tooth wave signal; a first generating unit that generates a signal indicating a period in which a voltage of the signal generated by the generating unit linearly and gradually rises or linearly and gradually falls; an amplifying unit that amplifies a voltage between both ends of the resistor; a comparing unit that compares the voltage of the signal amplified by the amplifying unit and a voltage generated by the generating unit; a second generating unit that generates a signal indicating a comparison result from the comparing unit in the period; and a detecting unit that detects the current flowing in the resistor on the basis of a ratio of a signal width of the signal from the second generating unit to a signal width of the signal from the first generating unit.

In a current detection circuit according to an aspect of the present invention, the detecting unit detects the signal width of each of the signals from the first and second generating units by holding, at a front edge and a back edge of the signal for which the signal width is to be detected, a count value of a counter that counts a period signal, and finding a difference between the count values.

A current detection circuit according to an aspect of the present invention further includes an insulating unit that electrically insulates the first and second generating units from the detecting unit and transmits signals from the first and second generating units to the detecting unit.

In a current detection circuit according to an aspect of the present invention, a potential at one terminal of the resistor is a reference potential of the first and second generating units.

A current detection circuit according to an aspect of the present invention further includes a selecting unit that selectively switches between the signals from the first and second generating units and transmits the signal to the detecting unit, and the detecting unit switches the selecting unit in accordance with a period of the signal from the first generating unit transmitted via the selecting unit.

According to these aspects, a voltage arising between both ends of the resistor connected between the power supply and the load is amplified by the amplifying unit and compared to the voltage of the saw-tooth wave signal or the triangle wave signal. The length of a signal indicating the comparison result in an inclined period in which the voltage of the saw-tooth wave signal or the triangle wave signal linearly and gradually rises or linearly and gradually falls, and the length of a signal indicating the inclined period, are detected, and the current flowing in the resistor is detected on the basis of a ratio of the detected lengths.

As a result, a ratio of the output voltage of the amplifier to the peak voltage of the saw-tooth wave signal or the triangle wave signal is calculated, and the current value is detected on the basis of that ratio, the value of the peak voltage, the amplification rate of the amplifying unit, and the resistance value of the resistor.

According to these aspects, for example, the signal indicating the inclined period and the signal indicating the comparison result are inputted to a timer having a so-called input capture function, and the lengths of these signals are detected in accordance with differences in counter count values held at the front edges and the back edges of the respective signals.

As a result, the length of the signal indicating the inclined period and the length of the signal indicating the comparison result can be detected with higher precision than when, for example, the counter count values, which change sequentially in interrupt processes at the front edges and back edges of the signals, are read out and a time difference thereof is detected.

According to these aspects, a generating circuit part that generates the signal indicating the inclined period in the signal indicating the comparison result is electrically insulated and isolated from a detection circuit part that detects the current on the basis of those signals, and the signals are transmitted from the generating circuit part to the detection circuit part.

As a result, the current flowing in the resistor is detected regardless of the reference potential at other circuit parts outside the detection circuit part.

According to these aspects, the signal indicating the inclined period in the signal indicating the comparison result are generated taking the potential at one of both ends of the resistor as a reference potential.

Accordingly, minute voltages between both ends of the resistor are amplified stably and with low noise, and thus current flowing in the resistor can be detected with high precision.

According to these aspects, the signal indicating the inclined period and the signal indicating the comparison result are selectively switched and transmitted from the generating circuit part to the detection circuit part. This switching is carried out in accordance with a signal period while the signal indicating the inclined period is being transmitted.

Accordingly, the signal width of the signal indicating the inclined period and the signal width of the signal indicating the comparison result are detected in time series. Additionally, if the signal width is not detected while the signal indicating the comparison result is being transmitted, current having a value of 0 can be detected in accordance with the signal width having a value of 0.

According to the foregoing, a ratio of the output voltage of the amplifier to the peak voltage of the saw-tooth wave signal or the triangle wave signal is calculated, and the current value is detected, without feedback caused by time delay, on the basis of that ratio, the value of the peak voltage, the amplification rate of the amplifying unit, and the resistance value of the resistor.

Accordingly, current can be detected in a wide dynamic range, with high precision, and with good step response.

### BRIEF DESCRIPTION OF DRAWINGS

FIG. 1 is a block diagram illustrating an example of the configuration of a current detection circuit according to a first embodiment of the present invention.

FIG. 2 is a circuit diagram illustrating an example of the configuration of an insulating circuit.

FIG. 3 is a circuit diagram illustrating an example of the configuration of a saw-tooth wave generator.

FIG. 4 is a timing chart illustrating operations of the current detection circuit according to the first embodiment of the present invention.

FIG. 5 is a flowchart illustrating a processing sequence carried out by a CPU in a period signal interrupt process.

FIG. 6 is a flowchart illustrating a processing sequence carried out by a CPU in a first timer interrupt process.

FIG. 7 is a flowchart illustrating a processing sequence carried out by a CPU in a second timer interrupt process.

FIG. 8 is a flowchart illustrating a processing sequence carried out by a CPU in a third timer interrupt process.

FIG. 9 is a block diagram illustrating an example of the configuration of a current detection circuit according to a variation on the first embodiment of the present invention.

FIG. 10 is a block diagram illustrating an example of the configuration of a current detection circuit according to a second embodiment of the present invention.

FIG. 11 is a timing chart illustrating operations of the current detection circuit according to the second embodiment of the present invention.

FIG. 12 is a flowchart illustrating a processing sequence carried out by a CPU in a second timer interrupt process.

FIG. 13 is a flowchart illustrating a processing sequence carried out by a CPU in a period timer interrupt process.

FIG. 14 is a flowchart illustrating a processing sequence carried out by a CPU in a first timer interrupt process.

FIG. 15 is a flowchart illustrating a processing sequence, carried out by a CPU, of a front edge value/back edge value readout subroutine.

### DETAILED DESCRIPTION OF PREFERRED EMBODIMENTS

The present invention will be described in detail hereinafter on the basis of drawings illustrating embodiments thereof.

### First Embodiment

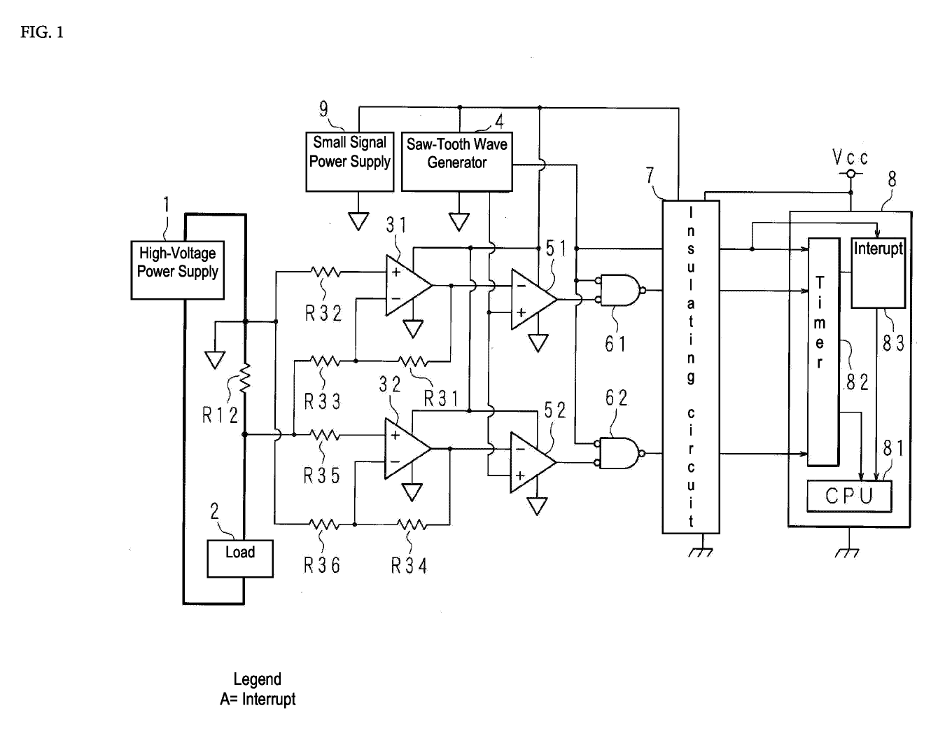

FIG. 1 is a block diagram illustrating an example of the configuration of a current detection circuit according to a first embodiment of the present invention. The current detection circuit includes: amplifiers (corresponding to an amplifying unit) 31 and 32 that amplify a voltage between both ends of resistor R12 connected between a high-voltage power supply (corresponding to a power supply) 1, containing a high-voltage battery, and a load 2; a saw-tooth wave generator (corresponding to a generating unit) 4 that generates a saw-tooth wave signal; and comparators (corresponding to a comparing unit) 51 and 52 that compare a voltage of the saw-tooth wave signal generated by the saw-tooth wave generator 4 with respective voltages amplified by the amplifiers 31 and 32. The saw-tooth wave generator 4 may be a triangle wave generator that generates a triangle wave signal.

The current detection circuit further includes: AND circuits (corresponding to a second generating unit) 61 and 62 that find individual negative logic ANDs for a second signal from the saw-tooth wave generator 4 (described in detail later) and output signals of the comparators 51 and 52; an insulating circuit (corresponding to an insulating unit) 7 that transmits an inputted signal to a later stage while electrically insulating the saw-tooth wave generator 4 and the AND circuits 61 and 62 from circuitry in the later stage; and a microcomputer (corresponding to a detecting unit) 8 that detects current flowing in the resistor R12 on the basis of the signal inputted via the insulating circuit 7.

The amplifiers 31 and 32, the saw-tooth wave generator 4, the comparators 51 and 52, and the AND circuits 61 and 62 take one end of the resistor R12, i.e. a connection point between one end of the high-voltage power supply 1 and the resistor R12, as a reference potential, and power is supplied from a small signal power supply 9 that generates a power supply voltage in response to the reference potential. The voltage of the power supplied by the small signal power supply 9 is 5 V, for example. Although the other end of the resistor R12 may be taken as the reference potential, it is preferable that the one end of the resistor R12 be taken as the reference potential in cases where, when the current flowing in the resistor R12 changes between large/small, problems arise with the reference potential fluctuating between low/high with respect to the one end of the high-voltage power supply 1. The microcomputer 8 and the insulating circuit 7 take ground potential as a reference potential, and Vcc at +5 V is supplied thereto.

The amplifier 31 includes an analog operational amplifier, with a resistor R31 connected between an output terminal and an inverting input terminal, a resistor R32 connected between a non-inverting input terminal and the one end of the resistor R12, and a resistor R33 connected between the inverting input terminal and the other end of the resistor R12. The amplifier 32 includes an operational amplifier, with a resistor R34 connected between an output terminal and an inverting input terminal, a resistor R35 connected between a non-inverting input terminal and the other end of the resistor R12, and a resistor R36 connected between the inverting input terminal and the one end of the resistor R12.

Accordingly, the amplifier 31 functions as an inverting amplifier that inverts and amplifies a negative voltage signal at the other end of the resistor R12 with respect to the one end of the resistor R12, and outputs a positive voltage signal. The amplifier 32 functions as a non-inverting amplifier that amplifies a positive voltage signal at the other end of the resistor R12 with respect to the one end of the resistor R12, without inverting the signal, and outputs a positive voltage signal. When, as in the present first embodiment, the amplifiers 31 and 32 are driven with a single power supply with respect to the reference potential, the voltage of the output signal from the amplifier 31 (called output voltage hereinafter) is 0 when the voltage at the other end of the resistor R12 with respect to the one end of the resistor R12 is positive, and the output voltage of the amplifier 32 is 0 when the voltage at the other end of the resistor R12 with respect to the one end of the resistor R12 is negative.

To cancel out input offset currents of the amplifiers 31 and 32, it is preferable that a resistance value of the resistor R32 match a parallel resistance value of the resistors R31 and R33, and that a resistance value of the resistor R35 match a parallel resistance value of the resistors R34 and R36. Additionally, a known offset compensation circuit may be provided to cancel out input offset voltages of the amplifiers 31 and 32. Furthermore, a circuit that samples and holds the voltage between both ends of the resistor R12 may be added as well.

The output terminals of the amplifiers 31 and 32 are connected to inverting input terminals of the comparators 51 and 52, respectively, and the saw-tooth wave signal from the saw-tooth wave generator 4 is inputted to the non-inverting input terminals of the comparators 51 and 52. As a result, output signals from the comparators 51 and 52 go to L (low) level (or H (high) level) if the voltage of the saw-tooth wave signal drops below (or rises above) the respective output voltages of the amplifiers 31 and 32.

The output signals of the comparators 51 and 52 are inputted to one of input terminals in both the AND circuits 61 and 62, and the second signal from the saw-tooth wave generator 4 is inputted into the other of the input terminals in both the AND circuits 61 and 62. The AND circuits 61 and 62 output signals indicating comparison results from the comparators 51 and 52, respectively, in a period where the second signal is at L level (corresponding to a period in which the voltage of a signal generated by the generating unit linearly and gradually increases or decreases).

The AND circuits 61 and 62 need not be used if the rising time of the saw-tooth wave signal is negligible. In this case, the comparators 51 and 52 correspond to the comparing unit and the second generating unit. The second signal and the output signals of the AND circuits 61 and 62 are inputted individually, via the insulating circuit 7, to a timer input terminal of the microcomputer 8, which has a so-called “input capture” function. Of the signal inputted to the timer input terminal of the microcomputer 8, the second signal is also inputted to an interrupt input terminal of the microcomputer 8, and generates an interrupt request.

The insulating circuit 7 will be described next.

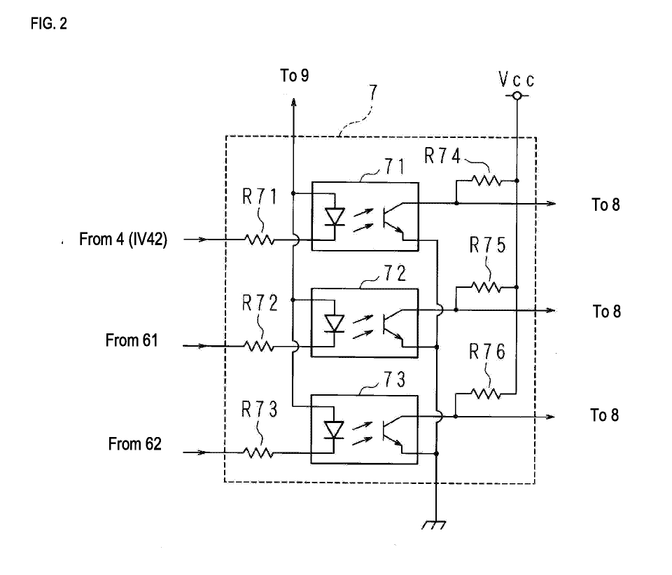

FIG. 2 is a circuit diagram illustrating an example of the configuration of the insulating circuit 7. The insulating circuit 7 includes photocouplers 71, 72, and 73, each of which has an LED (Light Emitting Diode) and a phototransistor that turns on when the LED emits light. In each of the photocouplers 71, 72, and 73, the anode of the LED is connected to the small signal power supply 9, and the emitter of the phototransistor is connected to ground potential. The photocouplers 71, 72, and 73 may be replaced with digital isolators or another isolator such as a pulse transformer.

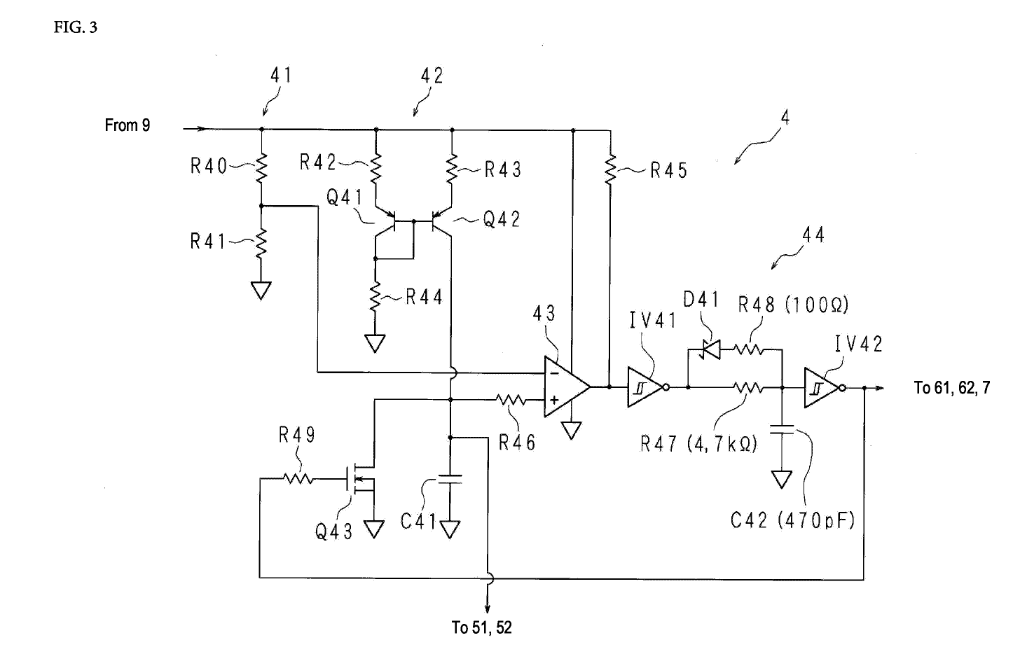

The cathode of the LED in the photocoupler 71 is connected, via a resistor R71, to the saw-tooth wave generator 4 (and more specifically, to an output terminal of an inverter IV42, which will be described later (see FIG. 3)). The cathodes of the LEDs in the photocouplers 72 and 73 are connected, via resistors R72 and R73, to the output terminals of the AND circuits 61 and 62. The collector of the phototransistor in the photocoupler 71 is pulled up to Vcc by a resistor R74, and is also connected to the timer input terminal and the interrupt input terminal of the microcomputer 8. The collectors of the phototransistors in the photocouplers 72 and 73 are pulled up by resistors R75 and R76, respectively, and are also connected to the timer input terminal of the microcomputer 8.

In the insulating circuit 7 having the above-described configuration, when an H level (or L level) signal is inputted via the resistors R71, R72, and R73 on the input side, the LEDs do not emit light (or emit light) and the phototransistors turn off (or turn on), and thus an H level (or L level) signal is inputted to the microcomputer 8.

Returning to FIG. 1, the microcomputer 8 includes a CPU (Central Processing Unit) 81, a timer 82, and an interrupt controller 83, and these elements are, along with ROM (Read Only Memory) and RAM (Random Access Memory) (not illustrated), connected to each other by a bus. The timer 82 includes a first timer, a second timer, and a third timer.

The first, second, and third timers in the timer 82 hold, in a capture register, a count value of a counter that counts a clock (corresponding to a period signal), at the falls and rises of a signal inputted to a timer input terminal of the corresponding timer (corresponding to a front edge and a back edge of a signal having a signal width to be detected), and generate an interrupt request. The CPU 81 can calculate differences in the count values held in the capture registers through interrupt processing, and accurately detect the signal width of the L level signal.

The interrupt controller 83 accepts an interrupt request from the interrupt input terminal and an interrupt request from the timer 82, and causes the CPU 81 to make an interrupt. In the first embodiment, the rise of the second signal inputted to the interrupt input terminal is accepted as an interrupt request, but the interrupt request is not limited thereto.

The saw-tooth wave generator 4 will be described next.

FIG. 3 is a circuit diagram illustrating an example of the configuration of the saw-tooth wave generator 4. The saw-tooth wave generator 4 includes: a divider 41, constituted of resistors R40 and R41, that divides the power supply voltage from the small signal power supply 9; a current mirror circuit 42; a capacitor C41 charged by a constant current from the small signal power supply 9 via the current mirror circuit 42; a comparator 43 that compares the voltage divided by the divider 41 with the voltage of the capacitor C41; and a delay unit 44 that delays the rise of an output signal from the comparator 43. The voltage of the capacitor C41 is inputted to the non-inverting input terminals of the comparators 51 and 52 described above.

The current mirror circuit 42 includes PNP-type transistors Q41 and Q42, the emitters of which are connected to the small signal power supply 9 via resistors R42 and R43, respectively. The collector and base of the transistor Q41 and the base of the transistor Q42 are connected to the reference potential via a resistor R44. One end of the collector of the transistor Q42 is connected to the other end of the capacitor C41 connected to the reference potential. According to this configuration, a signal having an inclined period in which the voltage linearly and gradually increases arises at the other end of the capacitor C41.

The comparator 43 is supplied with power from the small signal power supply 9, and an output terminal thereof is pulled up to the small signal power supply 9 by the resistor R45. The inverting input terminal of the comparator 43 is connected to the division point of the divider 41, and the non-inverting input terminal is connected to the other end of the capacitor C41 via a resistor R46. According to this configuration, the output signal of the comparator 43 goes to H level if the voltage at the other end of the capacitor C41 exceeds the divided voltage of the divider 41.

The delay unit 44 includes: an inverter IV41 having an input terminal connected to the output terminal of the comparator 43; a series circuit, constituted of a resistor R47 and a capacitor C42, that integrates an output voltage of the inverter IV41; and a Schmitt trigger-type inverter (corresponding to a first generating unit) IV42 having an input terminal connected to the connection point between the resistor R47 and the capacitor C42. A series circuit constituted of a Schottky barrier diode D41, the cathode of which is provided on the output terminal side of the inverter IV41, and a resistor R48 is connected between the output terminal of the inverter IV41 and the input terminal of the inverter IV42. The resistance values of the resistors R47 and R48 are, for example, 4.7 kΩ and 100 Ω, respectively, and the capacitance value of the capacitor C42 is, for example, 470 pF. According to this configuration, the fall of the output voltage of the comparator 43 is delayed by an integrated circuit of the delay unit 44.

The output signal from the inverter IV42 is the second signal mentioned above. This signal is inputted to one of the input terminals of the AND circuits 61 and 62 and the input side of the insulating circuit 7, and is applied to the gate of a transistor Q43, which is an N-channel FET (Field Effect Transistor), via a resistor R49. According to this configuration, when the output signal from the comparator 43 goes to H level, the transistor Q43 turns on, and the charge accumulated in the capacitor C41 is discharged.

Operations of the current detection circuit will be described in detail next, focusing on the saw-tooth wave generator 4, using a case where positive current flows from the one end of the high-voltage power supply 1 to the load 2 via the resistor R12 as an example. When negative current flows from the one end of the high-voltage power supply 1 to the load 2 via the resistor R12, the amplifier 31, the comparator 51, and the AND circuit 61 may instead be read as the amplifier 32, the comparator 52, and the AND circuit 62, respectively, in the following descriptions.

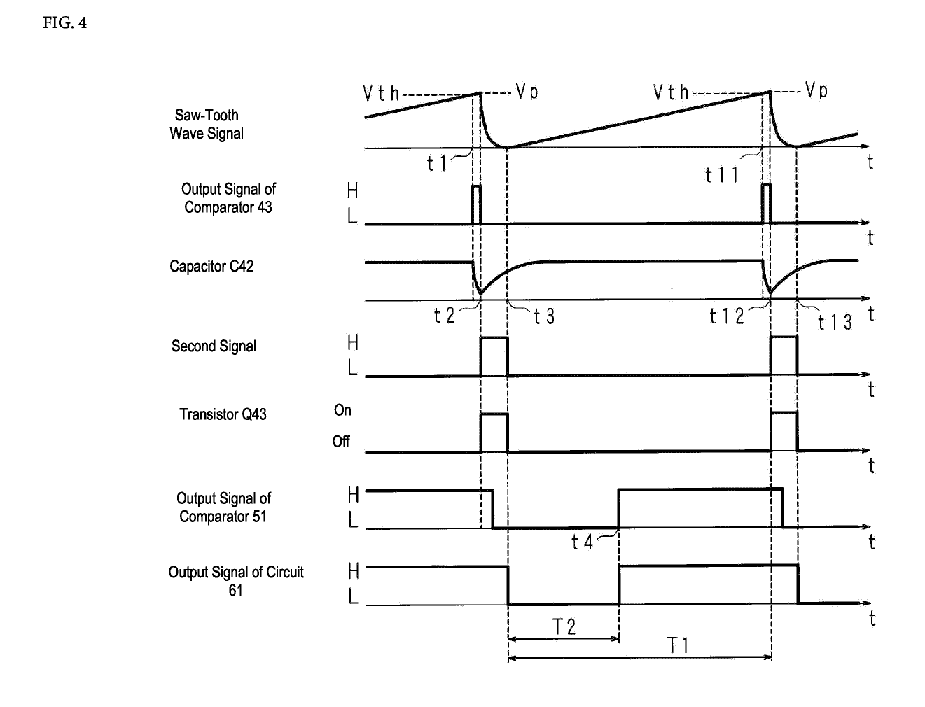

FIG. 4 is a timing chart illustrating operations of the current detection circuit according to the first embodiment of the present invention. In the seven timing charts illustrated in FIG. 4, the horizontal axis corresponds to the same time axis for all charts, whereas the vertical axis corresponds to the following, in order from the top section of the chart: the voltage of the saw-tooth wave signal (i.e. the voltage of the capacitor C41); the level of the output signal from the comparator 43; the voltage of the capacitor C42; the level of the second signal (i.e. of the output signal of the inverter IV42); the on/off state of the transistor Q43; the level of the output signal of the comparator 51; and the level of the output signal of the AND circuit 61. In the chart, Vth represents the divided voltage of the divider 41, whereas Vp represents a peak voltage of the saw-tooth wave signal.

If the voltage of the saw-tooth wave signal indicated in the uppermost section of FIG. 4 has linearly and gradually increased and exceeded Vth that time t1 (or t11), the output signal of the comparator 43 rises to H level, and that output signal is then inverted to L level by the inverter IV41; as such, the charge in the capacitor C42 is suddenly discharged via the diode D41 and the resistor R48. As a result, if at time t2 (or t12) the voltage in the capacitor C42 has dropped below a threshold voltage on the lower side of the inverter IV42, the output signal of the inverter IV42 (i.e. the second signal) rises to H level, and that signal turns the transistor Q43 on. Accordingly, the charge in the capacitor C41 is suddenly discharged, and the voltage of the saw-tooth wave signal suddenly drops. The voltage of the saw-tooth wave signal is Vp immediately before the transistor Q43 turns on. Compared to Vp, the amount by which the voltage in the capacitor C41 rises in the period from time t1 to t2 (or from t11 to t12) is negligible.

When the voltage in the capacitor C41 begins to decrease at time t2 (or t12), the output signal from the comparator 43 immediately falls to L level, and that output signal is inverted to H level by the inverter IV41; as such, the capacitor C42 is gradually charged via the resistor R47. As a result, if at time t3 (or t13) the voltage in the capacitor C42 has risen above a threshold voltage on the upper side of the inverter IV42, the output signal of the inverter IV42 (i.e. the second signal) falls to L level, and that signal turns the transistor Q43 off. Accordingly, the charging of the capacitor C41 begins again and the voltage of the saw-tooth wave signal linearly and gradually rises. Note that the charge in the capacitor C41 is adjusted so as to be completely discharged during the period from time t2 to t3 (or t12 to t13).

On the other hand, the output signal from the amplifier 31, which amplifies the voltage between both ends of the resistor R12, is inputted into the inverting input terminal of the comparator 51, into the non-inverting input terminal of which the saw-tooth wave signal from the saw-tooth wave generator 4 is inputted; the output signal changes from H level to L level at a point in time in the period from time t2 to t3 (or from t12 to t13), in which the voltage of the saw-tooth wave signal drops from Vp to 0. Conversely, the output signal of the comparator 51 changes from L level to H level at a time, such as time t4, during the period from time t3 to t12 where the voltage of the saw-tooth wave signal increases linearly and gradually from 0 to Vp.

The output signal of the AND circuit 61 that finds the negative logic AND of the second signal and the output signal of the comparator 51 is L level at time t3 (or t13), and is H level at time t4. Time t3 (or t13) is the starting point of the period in which the voltage of the saw-tooth wave signal increases linearly and gradually. In other words, as a result of the AND circuit 61 allowing the L level signal from the comparator 51 to pass only during the period when the second signal is L level, the fall (front edge) of the signal from the comparator 51 is outputted after being delayed until the front edge of the active low second signal.

If the length of the period when the second signal is L level, i.e. the period from time t3 to t12 when the voltage of the saw-tooth wave signal linearly and gradually rises, is represented by T1 and the length of the period from time t3 to t4 when the output signal of the AND circuit 61 is L level is represented by T2, the voltage of the saw-tooth wave signal at time t4 is Vp×(T2/T1). This voltage is equal to the voltage inputted to the inverting input terminal of the comparator 51 at time t4, i.e. the output voltage of the amplifier 31, and thus current i flowing from the high-voltage power supply 1 to the load 2 via the resistor R12 is calculated through the following Formula (1). Note that when calculating the current i flowing from the load 2 to the high-voltage power supply 1 via the resistor R12, a length T3 of the period when the output signal of the AND circuit 62 is L level may be detected, and in Formula (1), T2 may be replaced with T3 and 13 with the absolute value of the amplification rate of the amplifier 32.

I=Vp×(T2/T1)/(r×β) (1)

Where

r=the resistance value of the resistor R12, and

β=the absolute value of the amplification rate of the amplifier 31.

The accuracy of detecting the current i will be described next. As described above, the second signal and the output signal of the AND circuit 61 are inputted individually to the timer input terminal of the microcomputer 8 via the insulating circuit 7, and T1 and T2 are detected individually on the basis of the difference between the counter count values held in the capture register. T1 and T2 are numerical values used in Formula (1), and thus it is not absolutely necessary to detect by converting the values into time.

When the frequency of the clock counted by the counter of the timer 82 is represented by f, T1 and T2 are detected at an accuracy of 1/f, which corresponds to the period of the clock. In this case, to detect T1 as a numerical value greater than or equal to n bits (where n is a natural number), at a so-called resolution greater than or equal to n bits, a length t of the period when the second signal is L level, i.e. of the period when the voltage of the saw-tooth wave signal linearly and gradually rises, may be expressed through the following Formula (2).

t≥2̂nf (2)

Here, “̂” indicates exponentiation.

On the other hand, if the number of bits the CPU 81 can process in parallel is m (where m is a natural number greater than or equal to n), t may be set to a length within a range expressed by the following Formula (3), in light of Formula (2).

2̂n/f≤t≤2̂m/f (3)

For example, if the aforementioned clock frequency is 32 MHz, t may be set to 1024 μs as a boundary value in Formula (2) in order to detect T1 at a resolution of 15 bits. Additionally, if, for example, the peak voltage Vp of the saw-tooth wave signal is adjusted to 2.0 V and the capacitance value of the capacitor C41 is set to C=0.1 μF, a constant current I to be applied to the capacitor C41 by the current mirror circuit 42 is, based on the relational expression I×t=C×Vp, I=195 μA.

Voltage fluctuation in the small signal power supply 9, fluctuation in the resistance values of the resistors R40 and R41 that determine the division ratio of the divider 41, fluctuation in the resistance value of the resistor R12 connected between the high-voltage power supply 1 and the load 2, fluctuation in the amplification rates of the amplifiers 31 and 32, and so on can be given as factors that reduce the accuracy of detecting the current i. With respect to the capacitor C41, the voltage in which becomes the voltage of the saw-tooth wave signal, fluctuations in the capacitance value thereof appear as fluctuations in T1 in Formula (1); however, because T2 fluctuates at the same rate, this has not effect on the calculation result of Formula (1).

On the other hand, with respect to the resistors R40 and R41, it is preferable that the temperature characteristics and so on thereof be selected such that fluctuations in the resistance values thereof do not affect the division ratio. Additionally, the absolute value of the amplification rate of the amplifier 31 is the value of the ratio of the resistance value of the resistor R31 to the resistance value of the resistor R33, whereas the absolute value of the amplification rate of the amplifier 32 is a value obtained by adding 1 to the value of the ratio of the resistance value of the resistor R34 to the resistance value of the resistor R36, and it is preferable that these amplification rates also be set such that the effects of fluctuations in the resistance values cancel out.

The following will give a detailed description of the above-described operations of the microcomputer 8 using a flowchart. The processing described below is executed by the CPU 81 in accordance with a control program stored in advance in ROM (not illustrated).

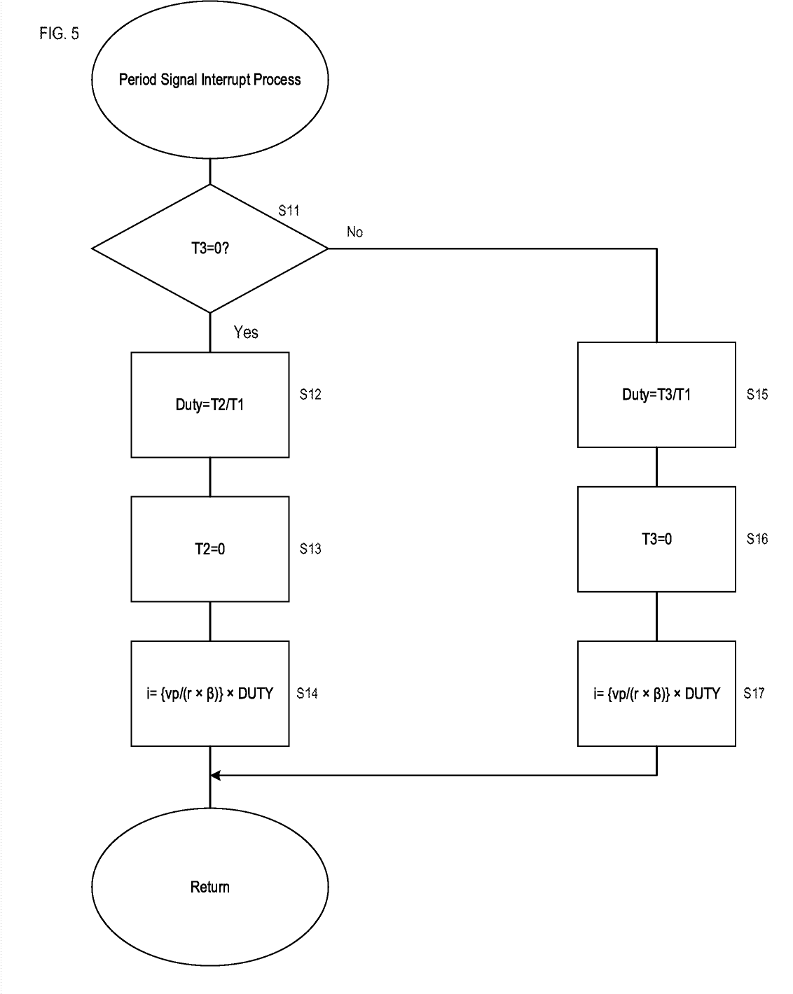

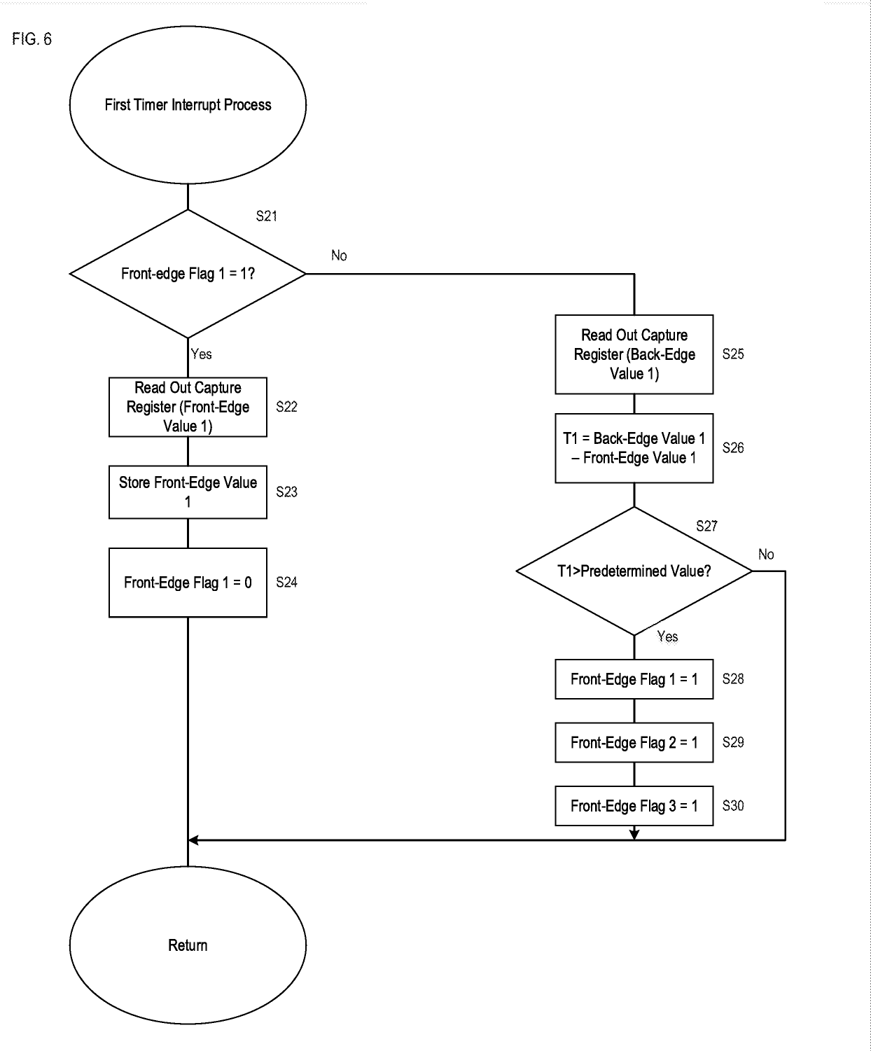

FIG. 5 is a flowchart illustrating a sequence of processing carried out by the CPU 81 in a period signal interrupt process, whereas FIGS. 6, 7, and 8 are flowcharts illustrating sequences of processing carried out by the CPU 81 in a first timer interrupt process, a second timer interrupt process, and a third timer interrupt process, respectively. The interrupt process of FIG. 5 is executed at the rise of the second signal. The interrupt processes of FIGS. 6, 7, and 8 are executed when the count values in the capture registers of the first timer, the second timer, and the third timer are held in response to the second signal, the output signal of the AND circuit 61, and the output signal of the AND circuit 62, respectively.

r and β used in the process illustrated in FIG. 5 represent the aforementioned resistance value of the resistor R12 and the absolute value of the amplification rates of the amplifiers 31 and 32, respectively. T3 represents the length of the period when the output signal of the AND circuit 62 is L level. A front-edge flag 1, a front-edge flag 2, and a front-edge flag 3 used in the processes of FIGS. 6, 7, and 8, respectively, are flags indicating an interrupt process at the front edge of the signal whose signal width is to be detected, and are stored in RAM (not illustrated). 0 is stored in the RAM as the initial values of T2 and T3. The value of T1 detected immediately before is stored in the RAM. The current i calculated through the processing in FIG. 5 assumes that the current flowing from the high-voltage power supply 1 to the load 2 via the resistor R12 is positive current.

When the period signal interrupt process of FIG. 5 is executed, the CPU 81 determines whether or not T3 stored in the RAM is 0 (S11). If T3 is 0 (SH:YES), i.e. if T3 has not been detected since the previous period signal interrupt process in response to the second signal, the CPU 81 finds a duty by dividing T2 by T1 (S12), and sets T2 to 0 for the next period signal interrupt process (S13). The CPU 81 then multiplies the result of dividing Vp by r×β with the duty to calculate the current i (S14), and then returns to the interrupted routine. Note that i is calculated as 0 if neither T2 nor T3 have been detected since the previous period signal interrupt process in response to the second signal.

On the other hand, if T3 is not 0 in step S11 (S11: NO), the CPU 81 finds the duty by dividing T3 by T1 (S15), and sets T3 to 0 for the next period signal interrupt process (S16). The CPU 81 then multiplies the result of dividing Vp by r×β with the duty to calculate the negative current i (S17), and then returns to the interrupted routine.

Next, when the first timer interrupt process illustrated in FIG. 6 is executed, the CPU 81 determines whether or not the front-edge flag 1 is 1 (S21); if the front-edge flag 1 is 1 (S21; YES), the CPU 81 reads out the content of the capture register as a front-edge value 1 (S22) and stores that value in the RAM (S23). The CPU 81 then clears the front-edge flag 1 to 0 (S24) and returns to the interrupted routine.

On the other hand, if the front-edge flag 1 is not 1 in step S21 (S21:NO), the CPU 81 reads out the content of the capture register as a back-edge value 1 (S25), and calculates the T1 by subtracting the front-edge value 1 stored in the RAM from the back-edge value 1 (S26). The calculated T1 is stored in the RAM (not illustrated; the same applies below). Then, the CPU 81 determines whether or not T1 is higher than a predetermined value (S27), and if T1 is not higher (S27:NO), the steps from step S28 on are skipped, and the process returns to the interrupted routine.

T1 is compared with the predetermined value in step S27 in order to discard T1 if the calculated T1 is the length of the period from time t2 to t3 in FIG. 4 (i.e. the period when the second signal is H level). The predetermined value is set to a value that is lower than the length of the period from time t3 to t12, and higher than the length of the period from time t2 to t3. If the process has returned immediately from step S27, the T1 calculated in the next first timer interrupt process is the length of the period from time t2 to t12, and is greater than the actual T1. However, in the first timer interrupt process following thereafter, the length of the period from time t3 to t12 is calculated correctly as T1.

If T1 is higher than the predetermined value in step S27 (S27: YES), the CPU 81 sets the front-edge flag 1 to 1 for the next first timer interrupt process (S28), further sets the front-edge flag 2 for the second timer interrupt process to 1 (S29), sets the front-edge flag 3 for the third timer interrupt process to 1 (S30), and then returns to the interrupted routine.

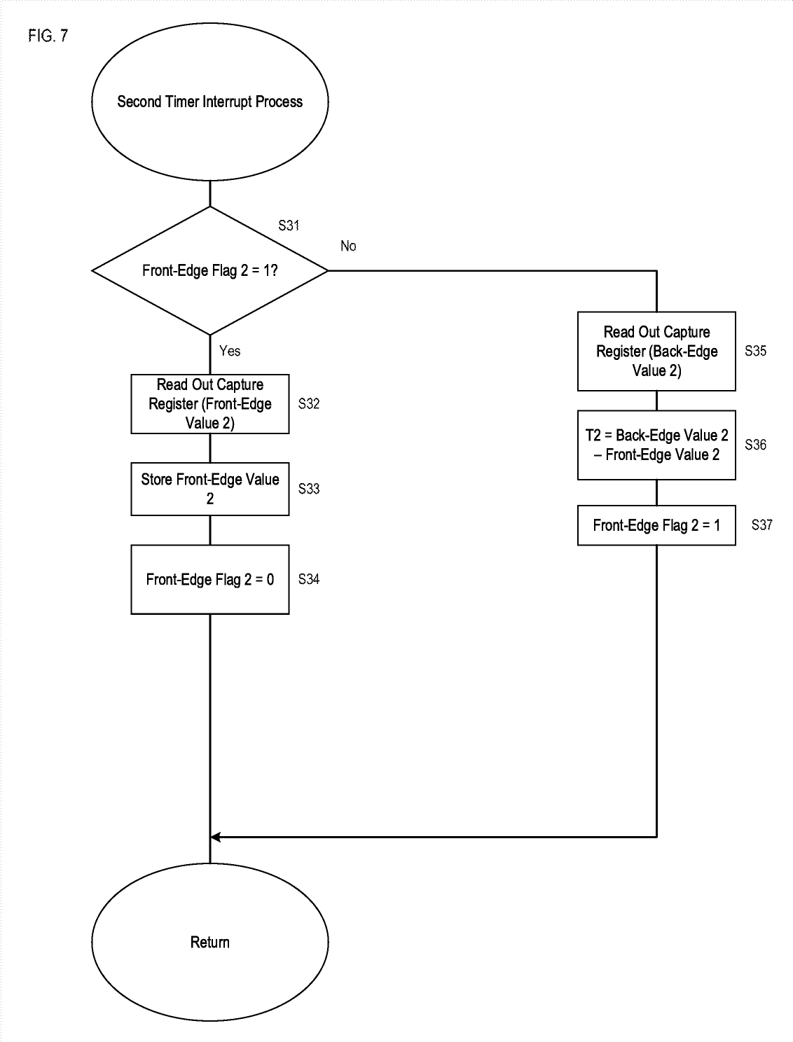

The processing from steps S31 to S35 in the second timer interrupt process illustrated in FIG. 7 simply replace the front-edge flag 1, the front-edge value 1, and the back-edge value 1 in the processing of steps S21 to S25 of the first timer interrupt process illustrated in FIG. 6 with the front-edge flag 2, a front-edge value 2, and a back-edge value 2, respectively, and thus descriptions thereof will be omitted.

In step S35, the CPU 81, which has read out the content of the capture register as the back-edge value 2, calculates T2 by subtracting the front-edge value 2 from the back-edge value 2 stored in the RAM (S36). The CPU 81 then sets the front-edge flag 2 for the next second timer interrupt process to 1 (S37) and returns to the interrupted routine.

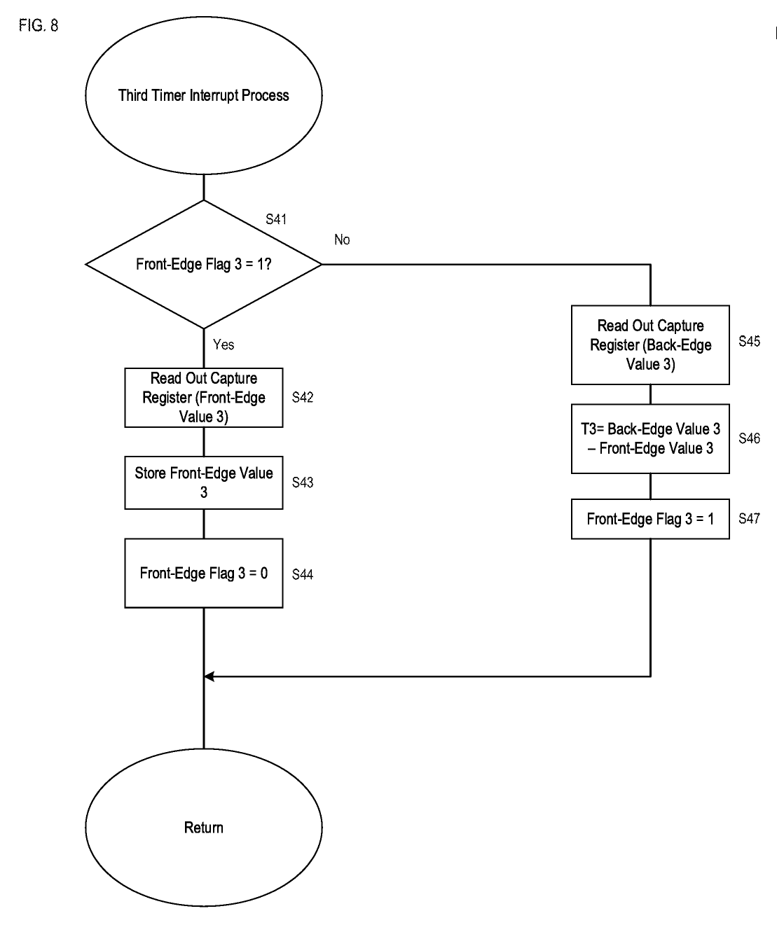

The processing from steps S41 to S45 in the third timer interrupt process illustrated in FIG. 8 simply replace the front-edge flag 2, the front-edge value 2, and the back-edge value 2 in the processing of steps S31 to S35 of the second interrupt process illustrated in FIG. 7 with the front-edge flag 3, a front-edge value 3, and a back-edge value 3, respectively, and thus descriptions thereof will be omitted.

In step S45, the CPU 81, which has read out the content of the capture register as the back-edge value 3, calculates T3 by subtracting the front-edge value 3 from the back-edge value 3 stored in the RAM (S46). The CPU 81 then sets the front-edge flag 3 for the next third timer interrupt process to 1 (S47) and returns to the interrupted routine.

According to the present first embodiment as described thus far, the voltage arising between both ends of the resistor R12 connected between the one end of the high-voltage power supply 1 and the load 2 is amplified by the amplifiers 31 and 32 and compared with the voltage of the saw-tooth wave signal by the comparators 51 and 52. The lengths T2 and T3 of the signals indicating the comparison results from the comparators 51 and 52 in an inclined period where the voltage of the saw-tooth wave signal linearly and gradually rises, and the length T1 of a signal indicating that inclined period, are then detected, and the current flowing in the resistor R12 is then detected on the basis of the ratio of the detected lengths.

Through this, the ratio of the output voltages of the amplifiers 31 and 32 to the peak voltage Vp of the saw-tooth wave signal is calculated, and the current value i is detected on the basis of the ratio, the peak voltage Vp, the absolute value β of the amplification rates of the amplifiers 31 and 32, and the resistance value r of the resistor R12.

Accordingly, current can be detected in a wide dynamic range, with high precision, and with good step response.

Additionally, according to the first embodiment, the second signal indicating the inclined period and the output signals of the AND circuits 61 and 62, which indicate the aforementioned comparison result, are inputted to the timer 82, which has a so-called input capture function, and the lengths of the signals are detected in accordance with the differences in the counter count values held at the front edges and back edges of each of the signals.

Thus the length of the signal indicating the inclined period and the lengths of the signals indicating the comparison results can be detected with higher precision than when, for example, the counter count values, which change sequentially in the interrupt processes at the front edges and back edges of the signals, are read out and a time difference thereof is detected.

Furthermore, according to the first embodiment, the saw-tooth wave generator 4 and the AND circuits 61 and 62, which generate the signal indicating the inclined period and the signals indicating the comparison results, are electrically insulated from the microcomputer 8, which detects current on the basis of those signals, by the insulating circuit 7. In this state, signals from the saw-tooth wave generator 4 and the AND circuits 61 and 62 are transmitted to the microcomputer 8.

As such, current flowing in the resistor R12 can be detected regardless of the reference potential at other circuit parts outside the microcomputer 8.

Further still, according to the first embodiment, minute voltages between both ends of the resistor R12 are amplified stably and with low noise, and thus current flowing in the resistor R12 can be detected with high precision.

Note that although the period in the saw-tooth wave signal where the voltage linearly and gradually rises is taken as the inclined period in the first embodiment, the inclined period is not limited thereto. For example, if the voltage of the saw-tooth wave signal gradually decreases toward the right in a period corresponding to the period from time t3 to t12 in FIG. 4, that period may be taken as the inclined period. In this case, by allowing the L level signal from the comparator 51 to pass only during the period when the second signal is at L level, the AND circuit 61 advances the rise (back edge) of the signal from the comparator 51 to the back edge of the active low second signal, and outputs the signal.

Additionally, for example, if the voltage of the saw-tooth wave signal linearly and gradually falls during the period from time t2 to t3 in FIG. 4, that period may be taken as the inclined period, or periods where the voltage of the saw-tooth wave signal linearly and gradually rises and falls may be connected and taken as the inclined period.

In the former of the above two cases, the above-described inclined period is indicated by the period where the second signal is at H level, and thus a signal obtained by inverting the second signal may be inputted to the other of the input terminals of the AND circuits 61 and 62 and to the insulating circuit. In the latter case, the length of the inclined period and the period of the saw-tooth wave signal substantially match, and thus the second signal indicated in FIG. 4 may be set to a fine pulse that rises at time t2 and then immediately falls. Furthermore, in this case, the unnecessary AND circuits 61 and 62 may be eliminated, and the output signals from the comparators 51 and 52 may be inputted to the insulating circuit 7. In a case where the AND circuits 61 and 62 are eliminated, the comparators 51 and 52 correspond to the comparing unit and the second generating unit.

Further still, a triangle wave signal may be used instead of the saw-tooth wave signal, for example. In this case, any one of the period in which the voltage of the triangle wave signal gradually rises, the period in which the voltage of the triangle wave signal gradually falls, and a period obtained by connecting those periods may be taken as the inclined period. Regardless of which period is taken as the inclined period, the operations of the current detection circuit are the same as those described above.

(Variation)

In the first embodiment, the output signals of the comparators 51 and 52 are transmitted to the microcomputer 8 via the AND circuits 61 and 62 and the insulating circuit 7; however, according to a variation on the first embodiment, a signal obtained by finding the OR of the output signals from the comparators 51 and 52 is transmitted to the microcomputer 8 via the AND circuit 61 and the insulating circuit 7.

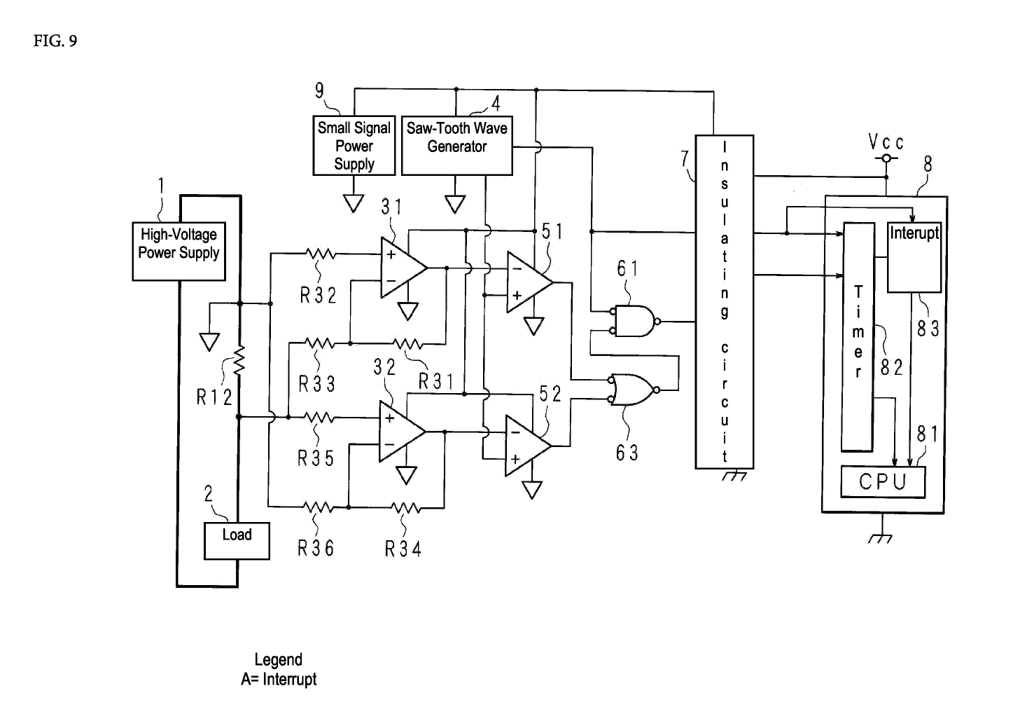

FIG. 9 is a block diagram illustrating an example of the configuration of a current detection circuit according to the variation on the first embodiment of the present invention. The current detection circuit illustrated in FIG. 9 differs from the current detection circuit according to the first embodiment and illustrated in FIG. 1 in that the AND circuit 62 has been removed, an OR circuit 63 that finds the negative logic OR of the output signals from the comparators 51 and 52 has been added, and an output terminal of the OR circuit 63 is connected to one of the input terminals of the AND circuit 61. Accordingly, it is sufficient for the insulating circuit 7 to have two circuits including the two photocouplers 71 and 72, and the timer 82 of the microcomputer 8 need not include the third timer.

According to the present variation, T2 and T3 described in the first embodiment are detected without being distinguished from each other, and thus the operations of the current detection circuit can be described using the same timing chart as the timing chart illustrated in FIG. 4. Additionally, in the period signal interrupt process illustrated in FIG. 5, the determination process of step S11 and the processing from steps S15 to S17 are unnecessary. Furthermore, the entire third timer interrupt process illustrated in FIG. 8 is unnecessary. The rest is the same as in the first embodiment.

According to the present variation on the first embodiment described above, aside from the positivity/negativity of the detected current not being differentiated, the same effects as in the first embodiment can be achieved even when using a microcomputer having a lower number of built-in timers.

### Second Embodiment

In the first embodiment, the signal widths of three signals (the second signal and the output signals of the AND circuits 61 and 62) are detected in parallel by the timer 82 of the microcomputer 8; however, in a second embodiment, the signal widths of the three signals are detected in time series by the timer 82.

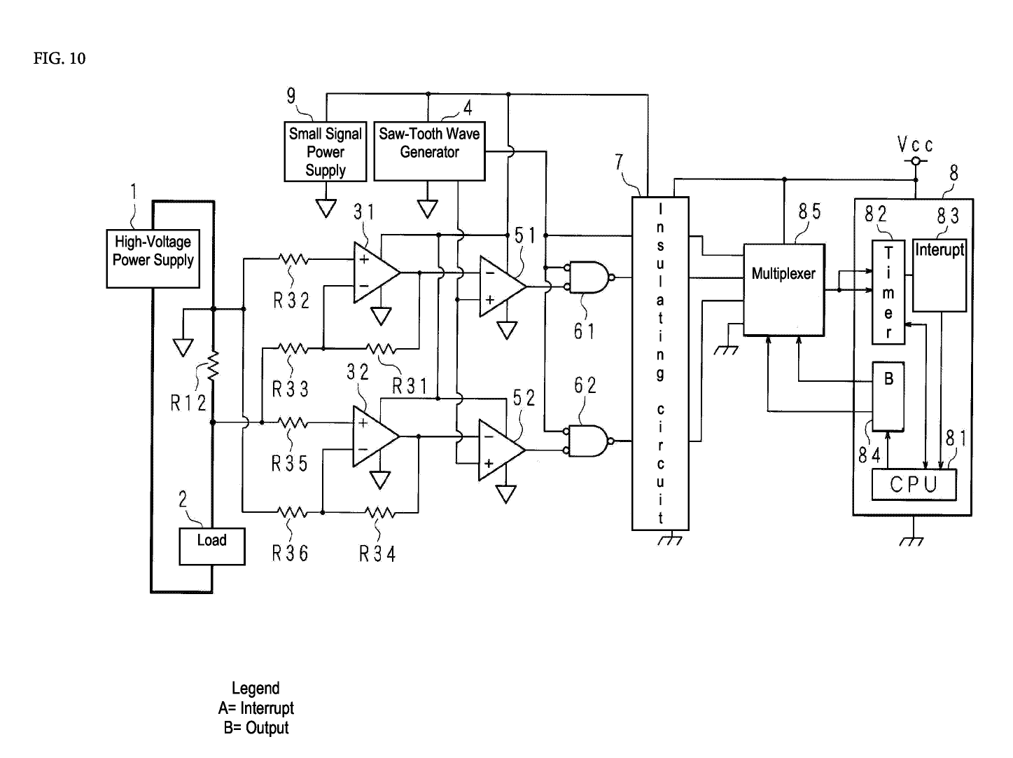

FIG. 10 is a block diagram illustrating an example of the configuration of a current detection circuit according to the second embodiment of the present invention. The current detection circuit illustrated in FIG. 10 differs from the current detection circuit according to the first embodiment and illustrated in FIG. 1 in that a multiplexer (corresponding to a selection unit; denoted as “MUX” hereinafter) 85 is connected between the insulating circuit 7 and the microcomputer 8, and an output port 84 has been added to the microcomputer 8. An output signal from the MUX 85 is inputted to first and second timer input terminals of the microcomputer 8. No signal is inputted to the interrupt input terminal of the microcomputer 8.

The timer 82 uses the first timer to detect the signal width of the signal inputted to the first timer input terminal, and uses the second timer to detect the period of the second signal inputted to the second timer input terminal or measure a period for switching the selection of the MUX 85. The timer 82 of the microcomputer 8 need not include the third timer. As in the first embodiment, the first timer holds a counter count value in the capture register at the rise and fall of the signal inputted to the first timer input terminal, and generates an interrupt request. When detecting the period of the second signal inputted to the second timer input terminal, the second timer holds a counter count value at the rise of the second signal in the capture register, and generates an interrupt request. The input capture function is canceled when the second timer counts the period.

The MUX 85 is supplied with power from Vcc, and selectively switches signals inputted to four selected input terminals among combinations of two-bit selection signals from the microcomputer 8, and outputs those signals to be transmitted to the first and second timer input terminals of the microcomputer 8.

The above-described second signal and the output signals of the AND circuits 61 and 62 are inputted individually to the first to third selected input terminals of the MUX 85, via the insulating circuit 7. The fourth selected input terminal of the MUX 85 is connected to ground potential. A two-bit selection signal is inputted to two selecting input terminals of the MUX 85 from the output port 84 of the microcomputer 8. According to this configuration, when the CPU 81 does not select any of the second signal and the output signals of the AND circuits 61 and 62 (this state will be called “unselected” hereinafter), an L level signal is forcefully outputted from the MUX 85.

Operations of the saw-tooth wave generator 4 will be described in detail next, using a case where positive current flows from the high-voltage power supply 1 to the load 2 as an example.

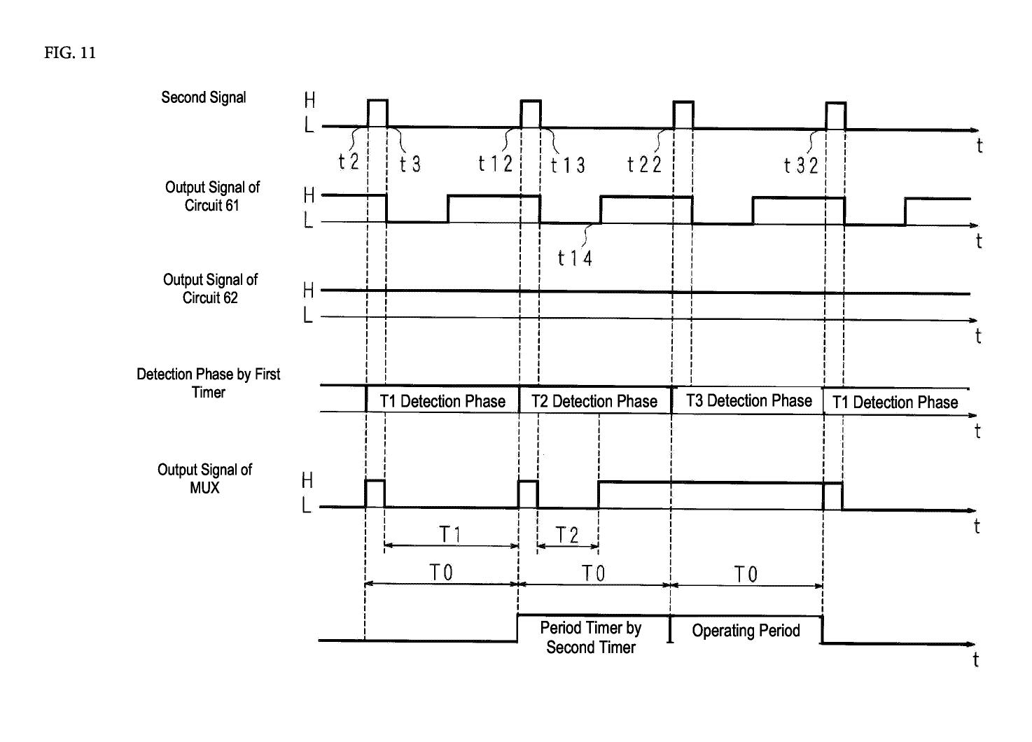

FIG. 11 is a timing chart illustrating operations of the current detection circuit according to the second embodiment of the present invention. In the six timing charts illustrated in FIG. 11, the horizontal axis corresponds to the same time axis for all charts, whereas the vertical axis corresponds to the following, in order from the top section of the chart: the level of the second signal; the level of the output signal of the AND circuit 61; the level of the output signal of the AND circuit 62; differentiation between phases of detection by the first timer of the timer 82; the level of the output signal of the MUX 85; and an operation period of the period timer implemented by the second timer of the timer 82.

In FIG. 11, a T1 detection phase, a T2 detection phase, and a T3 detection phase indicated in the phases of the detection by the first timer express phases in which the CPU 81 is outputting selection signals for selecting the second signal, the output signal of the AND circuit 61, and the output signal of the AND circuit 62, respectively. The differentiations between the detection phases are stored in RAM (not illustrated), and the initial state is the T1 detection phase.

During the T1 detection phase, the second signal, among the signals inputted to the selected input terminals of the MUX 85, is selected, and thus the counter count value of the second timer is held in the capture register at the rise of the second signal at time t2 and t12, and an interrupt request is generated. The CPU 81 detects a period TO of the second signal in the interrupt process carried out in response to this interrupt request.

Thereafter, the CPU 81 updates the detection phase to the T2 detection phase, and outputs a selection signal from the output port 84 so as to select the output signal of the AND circuit 61, among the signals inputted to the selected input terminals of the MUX 85. The CPU 81 furthermore starts a period timer for the period TO using the second timer.

Furthermore, in the T1 detection phase, the counter count value of the first timer is held in the capture register at the fall and rise of the second signal at time t3 and t12, and an interrupt request is generated. The CPU 81 detects the length T1 of the period in which the second signal is at L level in the interrupt process carried out in response to this interrupt request.

Next, in the T2 detection phase, the output signal of the AND circuit 61 is selected among the signals inputted to the selected input terminals of the MUX 85, and thus the counter count value of the first timer is held in the capture register at the fall and the rise of the output signal of the AND circuit 61 at time t13 and t14, and an interrupt request is generated. The CPU 81 detects the length T2 of the period in which the output signal of the AND circuit 61 is at L level in the interrupt process carried out in response to this interrupt request.

When the period timer by the second timer times out and an interrupt request occurs at time t22, an interrupt process is carried out in response to the interrupt request; in this interrupt process, the CPU 81 updates the detection phase to the T3 detection phase, and outputs a selection signal from the output port 84 in order to select the output signal of the AND circuit 62 among the signals inputted to the selected input terminals of the MUX 85. The CPU 81 furthermore restarts the period timer for the period TO using the second timer.

Next, in the T3 detection phase, the output signal of the AND circuit 62 is selected among the signals inputted to the selected input terminals of the MUX 85; however, in the present second embodiment, this output signal is kept at H level, and thus the length T3 of the period when the output signal of the AND circuit 62 is at L level is not detected. Nevertheless, the CPU 81 can end the T3 detection phase at time t32 in response to the period timer by the second timer timing out at time t32.

When the period timer by the second timer times out at time t32 and an interrupt request has been generated, an interrupt process is carried out in response to the interrupt request; in the interrupt process, the CPU 81 updates the detection phase to the T1 detection phase, and changes the second timer to an input capture configuration. The CPU 81 furthermore selects a ground potential signal, among the signals inputted to the selected input terminals of the MUX 85, for an extremely short time, and then outputs the selection signal from the output port 84 in order to select the second signal. As a result, the output signal of the MUX 85 invariably rises as time t32. In other words, in the T1 detection phase following time t32, the same exact operations as in the T1 detection phase following time t2 are repeated.

The following will give a detailed description of the above-described operations of the microcomputer 8 using a flowchart. The processing described below is executed by the CPU 81 in accordance with a control program stored in advance in ROM (not illustrated).

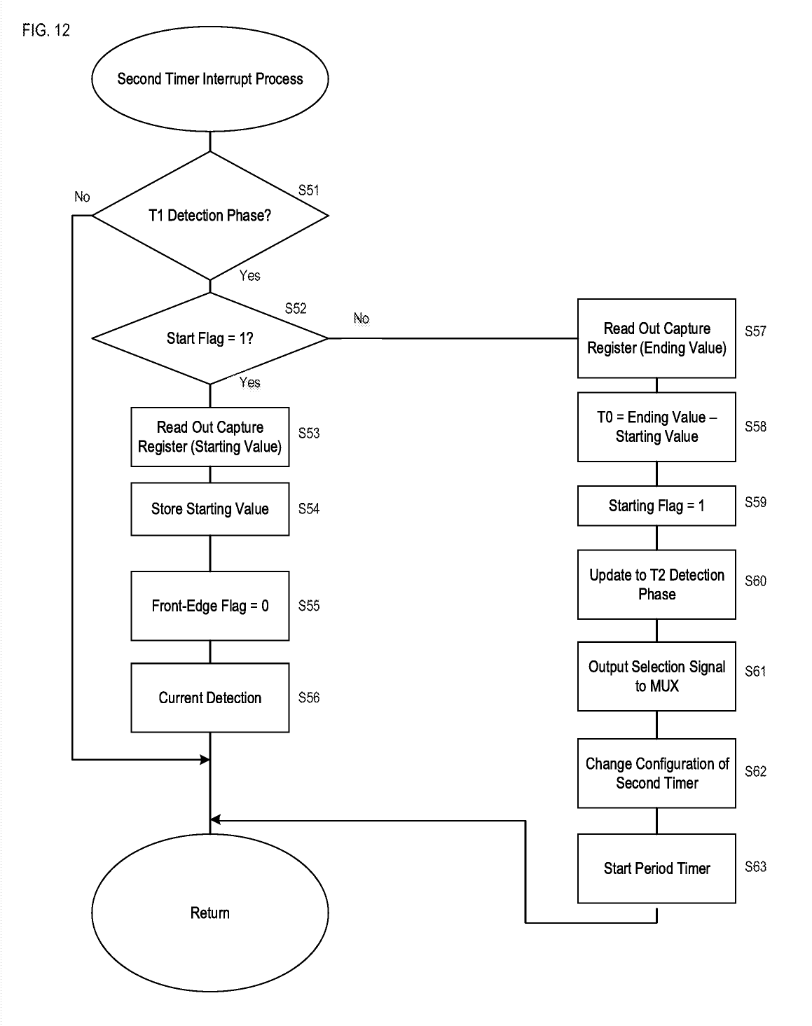

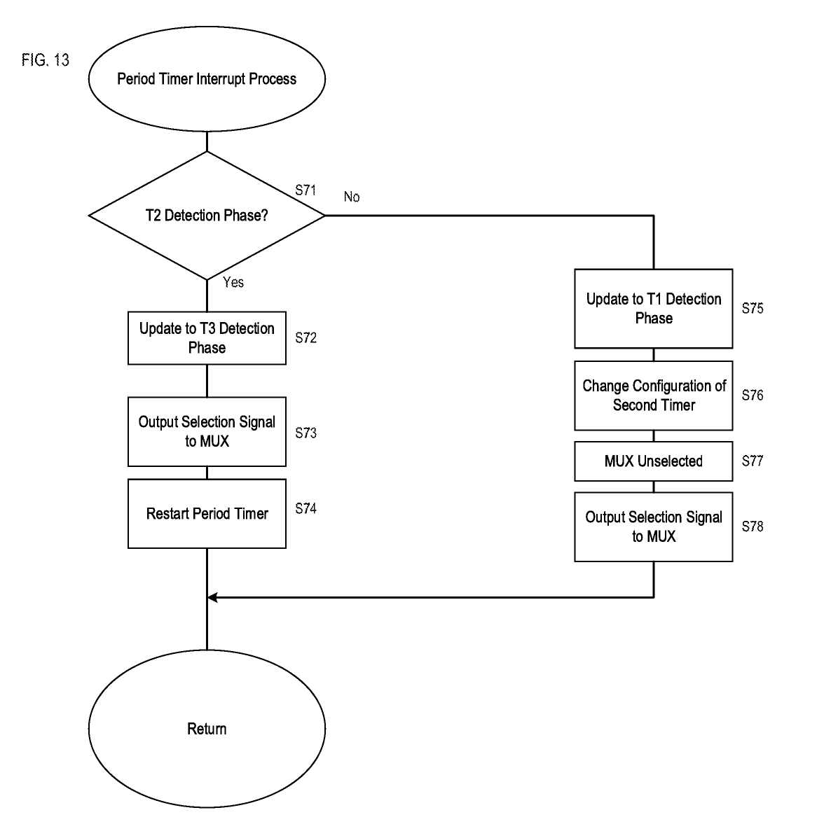

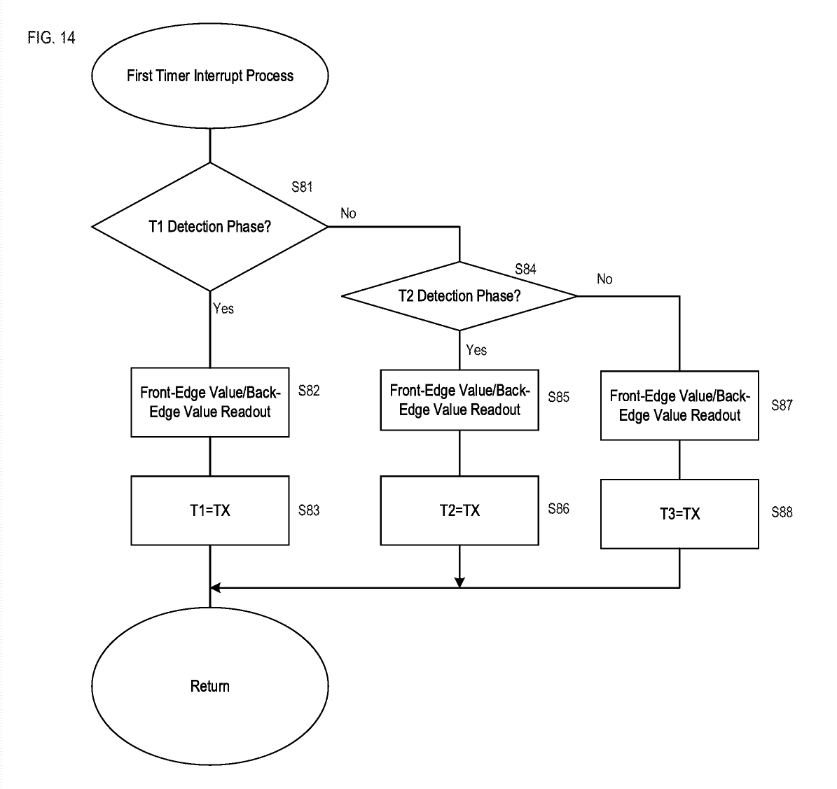

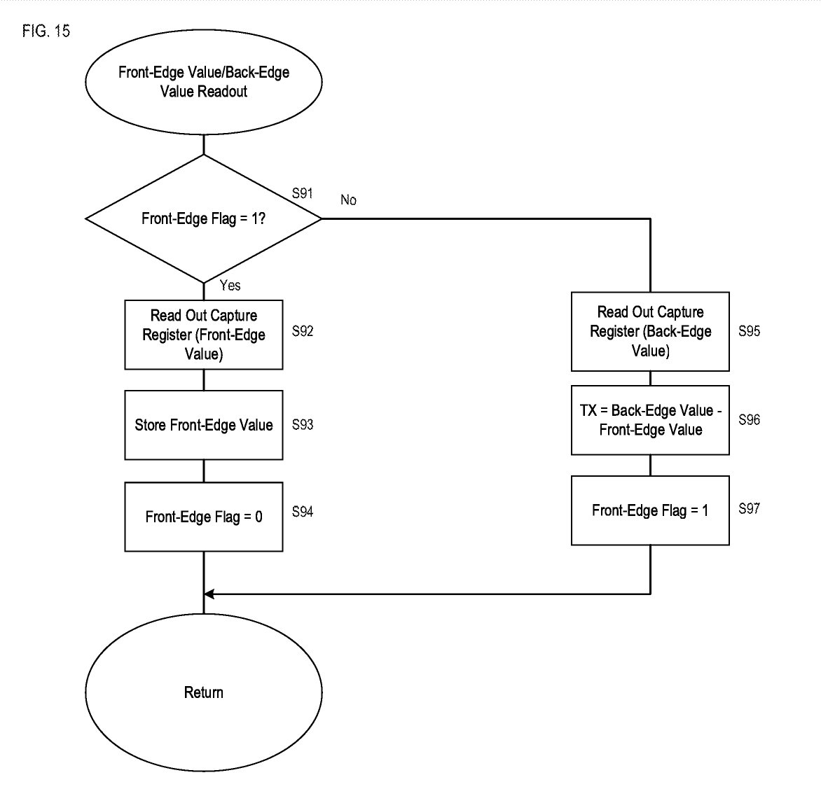

FIG. 12 is a flowchart illustrating a sequence of processing carried out by the CPU 81 in a second timer interrupt process; FIG. 13 is a flowchart illustrating a sequence of processing carried out by the CPU 81 in a period timer interrupt process; FIG. 14 is a flowchart illustrating a sequence of processing carried out by the CPU 81 in a first timer interrupt process; and FIG. 15 is a flowchart illustrating a sequence of processing carried out by the CPU 81 in a front edge value/back edge value readout subroutine. The interrupt processes of FIGS. 12 and 14 are executed when the count values of the second timer and the first timer, respectively, have been held in the capture register. The interrupt process of FIG. 13 is executed when the period timer by the second timer times out.

A start flag used in the processing of FIG. 12 is a flag indicating an interrupt process at the starting point of the signal whose period is to be detected, and is stored in RAM (not illustrated). A front-edge flag used in the process of FIG. 14 is a flag indicating an interrupt process at the front edge of the signal whose signal width is to be detected, and is stored in the RAM. The differentiations between the detection phases are also stored in the RAM. 0 is stored in the RAM as the initial values of T2 and T3. The value of T1 detected immediately before is stored in the RAM. The second timer has an input capture configuration.

When the second timer interrupt process of FIG. 12 is executed, the CPU 81 determines whether or not it is currently the T1 detection phase (S51), and if it is not currently the T1 detection phase (S51: NO), the CPU 81 returns to the interrupted routine without carrying out any processing. On the other hand, if it is currently the T1 detection phase (S51: YES), the CPU 81 determines whether or not the start flag is 1 (S52), and if the start flag is 1 (S52: YES), the CPU 81 reads out the content of the capture register as a starting value (S53) and stores that value in the RAM (S54).

Then, the CPU 81 clears the front-edge flag to 0 (S55), calls and executes the subroutine pertaining to current detection (S56), and then returns to the interrupted routine.

Note that the processing of the subroutine pertaining to current detection detects the current i on the basis of T1, T2, and T3 detected before time t2, the details of which are exactly the same as steps S11 to S17 in the period signal interrupt process according to the first embodiment and illustrated in FIG. 5; those details are therefore omitted from the flowchart, and will not be described here.

If in step S52 the start flag is not 1 (S52: NO), the CPU 81 reads out the content of the capture register as an ending value (S57), and calculates TO by subtracting the starting value stored in the RAM from the ending value (S58). The calculated TO is stored in the RAM (not illustrated; the same applies below). Then, the CPU 81 sets the start flag to 1 for the next second timer interrupt process (S59), updates the detection phase to the T2 detection phase (S60), and then outputs the selection signal from the output port 84 in order to select the output signal of the AND circuit 61 among the signals inputted to the selected input terminals of the MUX 85 (S61).

Next, the CPU 81 changes the configuration of the second timer so as to cancel the input capture configuration (S62), starts the period timer by the second timer (S63), and returns to the interrupted routine. In this case the period set in the period timer is the TO calculated in step S58.

Next, when the period timer interrupt process illustrated in FIG. 13 is executed, the CPU 81 determines whether or not it is currently the T2 detection phase (S71), and if it is currently the T2 detection phase (S71: YES), the CPU 81 updates the detection phase to the T3 detection phase (S72). The CPU 81 then outputs the selection signal from the output port 84 in order to select the output signal of the AND circuit 62 among the signals inputted to the selected input terminals of the MUX 85 (S73), restarts the period timer by the second timer (S74), and returns to the interrupted routine.

If in step S71 it is not currently the T2 detection phase (S71: NO), i.e. if it is currently the T3 detection phase, the CPU 81 updates the detection phase to the T1 detection phase (S75) and then once again changes the second timer to the input capture configuration (S76). Furthermore, the CPU 81 temporarily sets the MUX 85 to unselected (S77), outputs the selection signal from the output port 84 in order to select the second signal among the signals inputted to the selected input terminals of the MUX 85 (S78), and then returns to the interrupted routine.

Next, when the first timer interrupt process illustrated in FIG. 14 is executed, the CPU 81 determines whether or not it is currently the T1 detection phase (S81), and if it is currently the T1 detection phase (S81: YES), the CPU 81 calls and executes the front edge value/back edge value readout subroutine (S82), substitutes Tx calculated in the subroutine for T1 (S83), and returns to the interrupted routine.

If in step S81 it is not currently the T1 detection phase (S81: NO), the CPU 81 determines whether or not it is currently the T2 detection phase (S84), and if it is currently the T2 detection phase (S84: YES), the CPU 81 calls and executes the front edge value/back edge value readout subroutine (S85), substitutes Tx calculated in the subroutine for T2 (S86), and returns to the interrupted routine.

If in step S84 it is not currently the T2 detection phase (S84: NO), i.e. if it is currently the T3 detection phase, the CPU 81 calls and executes the front edge value/back edge value readout subroutine (S87), substitutes Tx calculated in the subroutine for T3 (S88), and returns to the interrupted routine.

Next, when the front edge value/back edge value readout subroutine illustrated in FIG. 15 has been called, the CPU 81 determines whether or not the front-edge flag is 1 (S91). If the front-edge flag is 1 (S91: YES), the CPU 81 reads out the content of the capture register as the front-edge value (S92), stores the value in the RAM (S93), clears the front-edge flag to 0 (S94), and returns to the called routine.

On the other hand, if the front-edge flag is not 1 in step S91 (S91: NO), the CPU 81 reads out the content of the capture register as the back-edge value (S95), and calculates the Tx by subtracting the front-edge value stored in the RAM from the back-edge value (S96). The calculated Tx is stored in the RAM (not illustrated). The CPU 81 then sets the front-edge flag to 1 (S97) and returns to the called routine.

According to the present second embodiment as described thus far, the signal indicating the above-described inclined period and the signals indicating the comparison results are selectively switched by the MUX 85 and transmitted to the microcomputer 8 from the saw-tooth wave generator 4 and the AND circuits 61 and 62. This switching is carried out in accordance with the signal period TO while the signal indicating the inclined period is being transmitted.

Accordingly, the signal width of the signal indicating the inclined period and the signal widths of the signals indicating the comparison results can be detected in time series, and the number of timers used by the microcomputer 8 is reduced by 1. Note that if the signal width is not detected while the signal indicating the comparison result is being transmitted, current having a value of 0 can be detected in accordance with the signal width having a value of 0.

The embodiments disclosed here are intended to be in all ways exemplary and in no ways limiting. The scope of the present invention is defined not by the foregoing descriptions but by the scope of the claims, and is intended to include all changes equivalent in meaning to and falling within the scope of the claims. The technical features disclosed in the embodiments can be combined with each other as well.

1. A current detection circuit that detects current flowing between a power supply and a load via a resistor, the circuit comprising:
a generating unit that generates a triangle wave signal or a saw-tooth wave signal;
a first generating unit that generates a signal indicating a period in which a voltage of the signal generated by the generating unit linearly and gradually rises or linearly and gradually falls;
an amplifying unit that amplifies a voltage between both ends of the resistor;
a comparing unit that compares the voltage of the signal amplified by the amplifying unit and a voltage generated by the generating unit;
a second generating unit that generates a signal indicating a comparison result from the comparing unit in the period; and
a detecting unit that detects the current flowing in the resistor on the basis of a ratio of a signal width of the signal from the second generating unit to a signal width of the signal from the first generating unit.

2. The current detection circuit according to claim 1, wherein the detecting unit detects the signal width of each of the signals from the first and second generating units by holding, at a front edge and a back edge of the signal for which the signal width is to be detected, a count value of a counter that counts a period signal, and finding a difference between the count values.

3. The current detection circuit according to claim 1, further comprising:
an insulating unit that electrically insulates the first and second generating units from the detecting unit and transmits signals from the first and second generating units to the detecting unit.

4. The current detection circuit according to claim 3, wherein a potential at one terminal of the resistor is a reference potential of the first and second generating units.

5. The current detection circuit according to claim 1, further comprising:
a selecting unit that selectively switches between the signals from the first and second generating units and transmits the signal to the detecting unit, wherein the detecting unit switches the selecting unit in accordance with a period of the signal from the first generating unit transmitted via the selecting unit.

6. The current detection circuit according to claim 2, further comprising:
an insulating unit that electrically insulates the first and second generating units from the detecting unit and transmits signals from the first and second generating units to the detecting unit.

7. The current detection circuit according to claim 2, further comprising:
a selecting unit that selectively switches between the signals from the first and second generating units and transmits the signal to the detecting unit,
wherein the detecting unit switches the selecting unit in accordance with a period of the signal from the first generating unit transmitted via the selecting unit.

8. The current detection circuit according to claim 3, further comprising:
a selecting unit that selectively switches between the signals from the first and second generating units and transmits the signal to the detecting unit,
wherein the detecting unit switches the selecting unit in accordance with a period of the signal from the first generating unit transmitted via the selecting unit.

9. The current detection circuit according to claim 4, further comprising:
a selecting unit that selectively switches between the signals from the first and second generating units and transmits the signal to the detecting unit,
wherein the detecting unit switches the selecting unit in accordance with a period of the signal from the first generating unit transmitted via the selecting unit.
